(19) United States
(12) Patent Application Publication
(10) Pub. No.: US 2025/0196468 A1
(43) Pub. Date: Jun. 19, 2025

(54) PROCESS FOR MAKING A LAYERED MATERIAL COMPRISING A MICRO- AND/OR NANOSTRUCTURED LAYER AND ADHESIVE SHEET FOR USE IN SAID PROCESS

(71) Applicant: Linari Engineering S.R.L., Pisa (IT)

(72) Inventor: Stefano LINARI, Pisa (IT)

(21) Appl. No.: 18/845,600

(22) PCT Filed: Mar. 10, 2023
(86) PCT No.: PCT/IB2023/052289

§ 371 Date: Sep. 10, 2024

(30) Foreign Application Priority Data
Mar. 11, 2022 (IT) 102022000004712

(51) Int. Cl. B32B 5/02; B32B 7/05; B32B 37/04; B32B 37/26; D01D 5/00; D01F 6/12; D01F 6/16; D04H 3/007; D04H 3/147

(52) U.S. Cl. CPC B32B 5/022; B32B 7/05; B32B 37/04; B32B 37/26; D01D 5/0007; D01F 6/12; D01F 6/16; D04H 3/007; D04H 3/147; B32B 2037/268; B32B 2262/0238; B32B 2262/0246; B32B 2262/124; B32B 2264/301; B32B 2307/208; B32B 2307/302; B32B 2307/7376; B32B 2309/02; B32B 2310/022; B32B 2310/0825; B32B 2327/12; D10B 2321/042; D10B 2321/08

(57) ABSTRACT

A process is disclosed for making a layered material comprising a micro- and/or nanostructured layer in a resin, including providing a substrate as a first layer; providing an adhesive sheet comprising at least one layer of nanofibre nonwoven fabric of a solidified resin; at least partially coating the substrate with the adhesive sheet; and heating the assembly comprising the substrate and adhesive sheet for a time interval (t) sufficient to bring the layer of nanofibre nonwoven fabric to a heating temperature (T) sufficient to cause a phase transition of the layer of nanofibre nonwoven fabric, to generate a micro- and/or nanostructure of localized accumulations of thermosetting acrylic resin and/or thermoplastic resin. The layer of nanofibre nonwoven fabric in thermosetting acrylic resin and/or thermoplastic resin of the adhesive sheet is supplemented with at least a plurality of nano-elements in a material different from the resin of the adhesive sheet.

### TECHNICAL FIELD

The present invention concerns a process for making a layered material comprising a micro- and/or nanostructured layer and an adhesive sheet employed in said process. In particular, the present invention relates to making a layered material that comprises a micro- and/or nanostructure of localized accumulations of resin, for example thermosetting acrylic resin, such as polycyanoacrylate, or thermoplastic resin, such as polyvinylidene fluoride.

### BACKGROUND

In the context of the study of acrylic resins, in particular thermosetting acrylic resins, such as for example cyanoacrylate monomers, commonly known as superglues or instant adhesives, it is known that these are highly reactive and low viscosity liquids. They are widely used to repair rubber, plastic and metallic parts in industrial and domestic applications, to seal tissue lesions in surgical and medical procedures, as well as for fingerprinting in forensic laboratories. By polymerizing in a few seconds in the presence of nucleophiles or traces of weak bases, such as for example environmental humidity, they are able to form mechanically strong polymers with excellent adhesion properties, low toxicity and biocompatibility.

These peculiar characteristics are the basis of a growing interest in the development of applications of such resins, in particular in the nanotechnological field. With specific reference to nanotechnologies, it is known to make nanofibres of thermosetting acrylic resins by electrospinning. This technique gives rise to a layer of nanofibre nonwoven fabric that can be used to coat surfaces. However, the layer thus obtained presents itself in the form of a particularly delicate web that makes a subsequent processing thereof quite difficult. Moreover, this technique has not yet permitted to use the nanofibre web as an adhesive for bonding other elements to a substrate.

Similarly, it is known to employ electrospinning for making a layer of nanofibre nonwoven fabric of a thermoplastic resin for the subsequent use thereof for the coating of supports in flexible material, like for example paper. Also in this case the layer obtained is in the form of a particularly delicate web, which makes a subsequent processing thereof quite difficult and correlated to a high number of waste.

### OBJECTS AND SUMMARY OF THE INVENTION

In light of the above, the problem underlying the present invention is to devise a process for making a layered material comprising a micro- and/or nanostructured layer in a resin, whether it is thermoplastic or thermosetting acrylic one, which is easily and industrially implementable.

Within the scope of this problem, an object of the present invention is to devise a process for making a layered material comprising a micro- and/or nanostructured layer in a resin that allows a plurality of nano-elements to be bound to a substrate in an extremely firm manner and according to a highly homogeneous distribution.

In accordance with a first aspect thereof, the invention therefore concerns a process for making a layered material comprising a micro- and/or nanostructured layer in a resin comprising the steps consisting in:
providing a substrate configured to constitute a first layer of the layered material;
providing an adhesive sheet comprising at least one layer of nanofibre nonwoven fabric of a thermosetting acrylic resin and/or of a solidified thermoplastic resin;
at least partially coating the substrate with the adhesive sheet; and
heating the assembly comprising the substrate coated by the adhesive sheet for a time interval sufficient to bring the layer of nanofibre nonwoven fabric to a heating temperature sufficient to cause a phase transition of the layer of nanofibre nonwoven fabric such as to generate a micro- and/or nanostructure of localized accumulations of resin.

According to the present invention the step of providing the adhesive sheet comprises supplementing the layer of nanofibre nonwoven fabric of thermosetting acrylic resin and/or thermoplastic resin of the adhesive sheet with at least a plurality of nano-elements in a material different from the thermosetting acrylic resin and/or from the thermoplastic resin.

Within the scope of the present description and in the appended claims “different material” means a material that is different by chemical composition and/or by morphology.

The Applicant has identified that with the process according to the invention it becomes possible supplementing with active material and thus to obtain a precise positioning and a reliable bond of said active material on the substrate.

It is also possible to apply the layer of nanofibre nonwoven fabric of solidified resin on any substrate in a simple manner and without deteriorating it, making said layer according to different and highly precise geometries.

The present invention may have at least one of the preferred following features; the latter may in particular be combined with one another as desired in order to meet specific application needs.

Preferably, the at least one plurality of nano-elements in a material different from the thermosetting acrylic resin and/or from the thermoplastic resin comprises at least one of: a plurality of nanoparticles, a plurality of nanotubes and a plurality of second nanofibres.

Preferably, the plurality of second nanofibres comprises a first plurality of second nanofibres made in a material characterized by having a roll-off angle of less than 65°, preferably less than 20°, more preferably less than 5°, when applied as a coating of a surface, such as in particular polytetrafluoroethylene and derivatives thereof.

Alternatively or additionally, the plurality of second nanofibres comprises a second plurality of second nanofibres made in an elastomer, preferably polyurethane and derivatives thereof.

According to a variant of the invention, the solidified thermosetting acrylic resin is polycyanoacrylate (PECA).

Preferably, the heating temperature is comprised between 150° C. and 260° C., more preferably the heating temperature is comprised between 160° C. and 250° C., even more preferably the heating temperature is equal to about at least 170° C., such as comprised between 170° C. and 240° C.

More preferably, the heating temperature is comprised between 150° C. and 190° C., more preferably the heating temperature is comprised between 160° C. and 180° C., even more preferably the heating temperature is equal to about at least 170° C., such as comprised between 170° C. and 175° C.

According to a variant of the invention, the thermosetting acrylic resin is polycyanoacrylate (PECA) with molecular weight of at least 15,000 Da (2.49081·10⁻²³ kg) and the heating temperature is comprised between 190° C. and 260° C., more preferably the heating temperature is comprised between 200° C. and 250° C., even more preferably the heating temperature is comprised between 210° C. and 240° C.

According to another variant of the invention, the solidified thermoplastic resin is polyvinylidene fluoride (PVDF).

Preferably, the heating temperature is comprised between 130° C. and 170° C., more preferably the heating temperature is comprised between 140° C. and 160° C., even more preferably the heating temperature is equal to about at least 150° C., such as comprised between 150° C. and 155° C.

According to a variant of the invention, the substrate is selected from the group consisting of metal, ceramic, glass, stone and polymeric material.

According to a variant of the invention, the substrate is for example paper in sheets, panels and/or rolls.

Preferably, the step of heating the assembly comprising the substrate coated by the adhesive sheet takes place by applying to the substrate and/or to the adhesive sheet electromagnetic radiations, for example by infrared heating, and/or by applying to the substrate and/or to the adhesive sheet heat by conduction and/or by convection.

Preferably, for a metal substrate, the step of heating the assembly comprising the substrate coated by the adhesive sheet takes place by applying eddy electric currents to the substrate, for example by induction heating.

Advantageously, the application of heat by induction heating of the substrate is particularly efficient, allowing to reduce the duration of the heating step necessary to cause a phase transition of the layer of nanofibre nonwoven fabric of the adhesive sheet.

According to a variant of the invention, the time interval in which the assembly comprising the substrate coated by the adhesive sheet is heated is equal to at least 1 second, such as for example equal to at least 30 seconds or equal to at least 1 minute.

Advantageously, these short times of the heating step also allow substrates having softening temperature and/or degradation temperature lower than the heating temperature to be used in the process, if the substrate also has a low thermal conductivity.

Alternatively, the time interval in which the assembly comprising the substrate coated by the adhesive sheet is heated is equal to at least 1 minute, such as for example equal to at least 5 minutes.

More preferably, the time interval in which the assembly comprising the substrate coated by the adhesive sheet is heated is equal to at least 10 minutes.

According to a variant of the invention, the layer of nanofibre nonwoven fabric has a thickness comprised between 3-5 g/m².

Preferably, the layer of nanofibre nonwoven fabric has porosity greater than 50%, preferably greater than 60%, more preferably greater than 70%.

Preferably, the layer of nanofibre nonwoven fabric is formed by nanofibres having a diameter comprised between 200-1500 nm, preferably between 200-400 nm.

In a variant of the invention, the step of supplementing comprises immersing the layer of nanofibre nonwoven fabric in a solution comprising a dispersion of nano-elements and/or spraying said layer with a solution comprising a dispersion of nano-elements.

Preferably, the nano-elements are selected from the group consisting of conductive nano-elements, such as in particular metallic nano-elements, graphene nano-elements and/or carbon nano-elements; semiconductor nano-elements, such as in particular quantum dots; nano-elements in bioactive material, such as in particular titanium and copper dioxide or alloys thereof; and magnetic nano-elements, such as in particular metallic or metal oxide nano-elements, such as for example magnetite.

In a variant of the invention, the process comprises the additional step of applying a magnetic field to the layered material to orient the nano-elements, in case the nano-elements are magnetic nano-elements.

Preferably, the nano-elements are second nanofibres made in a material characterized by having a roll-off angle of less than 65°, preferably less than 20°, more preferably less than 5°, when applied to a surface as a coating, such as in particular polytetrafluoroethylene.

Alternatively or additionally, the nano-elements are second nanofibres made in an elastomer, such as in particular polyurethane.

In a variant of the invention, the step of providing the adhesive sheet comprises making the layer of nanofibre nonwoven fabric by electrospinning.

Preferably, the step of supplementing comprises making the layer of nanofibre nonwoven fabric by electrospinning of nanofibres of at least two distinct materials, of which a first material of the at least two distinct materials is the thermosetting acrylic resin and/or the thermoplastic resin and a second material of the at least two distinct materials is a material different from the thermosetting acrylic resin and/or the thermoplastic resin.

More preferably, the second material of the at least two distinct materials is an elastomer, such as in particular polyurethane.

More preferably, the step of making the layer of nanofibre nonwoven fabric by electrospinning nanofibres in at least two distinct materials comprises making the layer of nonwoven fabric in a plurality of sub-layers, wherein in each sub-layer a material of the at least two distinct materials is present in a prevalent concentration, e.g. it is present in a concentration greater than 50%, preferably greater than 60%, more preferably greater than 70%.

Alternatively or additionally, the second material of the at least two distinct materials is a material characterized by having a roll-off angle of less than 65°, preferably less than 20°, more preferably less than 5° when applied to a surface as a coating, such as in particular polytetrafluoroethylene.

According to a variant of the invention, the adhesive sheet additionally comprises a peelable support layer.

Preferably, the peelable support layer is removed from the layer of nanofibre nonwoven fabric or from the micro- and/or nanostructure of localized accumulations of thermosetting acrylic resin and/or of thermoplastic resin before or after the heating step.

Preferably, the peelable support layer is made of silicone-impregnated cellulose.

In a variant of the invention, the process comprises the additional step of coating the layer of nanofibre nonwoven fabric with a second substrate subsequent to the removal step of the peelable support layer and prior to the heating step.

In accordance with a further aspect, the invention also concerns an adhesive sheet for use in a process for making a layered material comprising a micro- and/or nanostructured layer in a resin according to the invention, which comprises a layer of nanofibre nonwoven fabric of a solidified thermosetting acrylic resin, in particular polycyanoacrylate and/or in a solidified thermoplastic resin, in particular polyvinylidene fluoride.

The layer of nanofibre nonwoven fabric is supplemented with at least a plurality of nano-elements in a material different from the thermosetting acrylic resin and/or a thermoplastic resin, in particular conductive nano-elements, nano-elements of a semiconductor and/or bioactive nano-elements, and/or magnetic nano-elements, and/or with nano-elements made in the form of second nanofibres in a material different from the thermosetting acrylic resin and/or a thermoplastic resin, in particular second nanofibres in polytetrafluoroethylene.

In a variant of the invention, the adhesive sheet additionally comprises a peelable support layer, in particular a silicone-impregnated cellulose layer.

Preferably, the adhesive sheet is made into a spool.

In a variant of the invention, the adhesive sheet comprises a layer of nanofibre nonwoven fabric of a thermosetting acrylic resin, in particular polycyanoacrylate, and/or in a solidified thermoplastic resin, in particular polyvinylidene fluoride, wherein the layer of nanofibre nonwoven fabric is supplemented with nano-elements made in the form of a first plurality of second nanofibres in a material different from the thermosetting acrylic resin and/or from the solidified thermoplastic resin, in particular a first plurality of second nanofibres in an elastomer, such as in particular polyurethane.

In detail, the layer of nanofibre nonwoven fabric comprises a plurality of sub-layers, wherein in each sub-layer the thermosetting acrylic resin or the material that is different from the thermosetting acrylic resin is alternately present in a prevalent concentration.

Preferably, the layer of nanofibre nonwoven fabric is supplemented with at least a plurality of nano-elements in a material different from the thermosetting acrylic resin and/or from the solidified thermoplastic resin, in particular conductive nano-elements, nano-elements of a semiconductor and/or bioactive nano-elements, and/or magnetic nano-elements, and/or with nano-elements made in the form of at least a second plurality of second nanofibres in a material different from the thermosetting acrylic resin and/or from the solidified thermoplastic resin, in particular second nanofibres in polytetrafluoroethylene.

More preferably, the at least one second plurality of second nanofibres is made in a material characterized by having a roll-off angle of less than 65°, preferably less than 20°, more preferably less than 5°, when applied as a coating of a surface.

### BRIEF DESCRIPTION OF THE DRAWINGS

Further characteristics and advantages of the present invention will become clearer from the following detailed description of the preferred embodiments thereof, with reference to the appended drawings.

The different features in the individual configurations can be combined with each other as desired according to the above description, if the advantages resulting specifically from a particular combination are to be availed of.

In such drawings:

FIG. 1 is a block diagram of the process for making a layered material comprising a micro- and/or nanostructured adhesive layer according to the present invention;

FIG. 2a is a schematic representation of a first embodiment of an adhesive sheet according to the present invention employable in the process of FIG. 1 and made available in the form of a spool;

FIG. 2b is a schematic representation of the step of the process of FIG. 1 in which a substrate is coated with the adhesive sheet of FIG. 2a;

FIG. 3a is a schematic top view of a layered material obtained through the process of FIG. 1;

FIG. 3b is a side elevational view of the layered material of FIG. 3a;

FIG. 4a is a schematic view of a layer of nanofibre nonwoven fabric composing the adhesive sheet employed in a preferred embodiment of the process for making a layered material according to the present invention;

FIG. 4b is a side elevational view of a layered material obtained starting from the adhesive sheet according to FIG. 4a;

FIG. 5 is a side elevational view of a layered material obtained according to a preferred embodiment of the process for making a layered material according to the present invention; and

FIG. 6 is a schematic representation of an adhesive sheet in accordance with a second preferred embodiment of the present invention employable in the process of FIG. 1.

### DETAILED DESCRIPTION OF THE INVENTION

For the illustration of the drawings, use is made in the following description of identical numerals or symbols to indicate construction elements with the same function. Moreover, for clarity of illustration, certain references may not be repeated in all drawings.

While the invention is susceptible to various modifications and alternative constructions, certain preferred embodiments are shown in the drawings and are described hereinbelow in detail. It must in any case be understood that there is no intention to limit the invention to the specific embodiment illustrated, but, on the contrary, the invention intends covering all the modifications, alternative and equivalent constructions that fall within the scope of the invention as defined in the claims.

The use of “for example”, “etc.”, “or” indicates non-exclusive alternatives without limitation, unless otherwise indicated. The use of “comprises” and “includes” means “comprises or includes, but not limited to”, unless otherwise indicated.

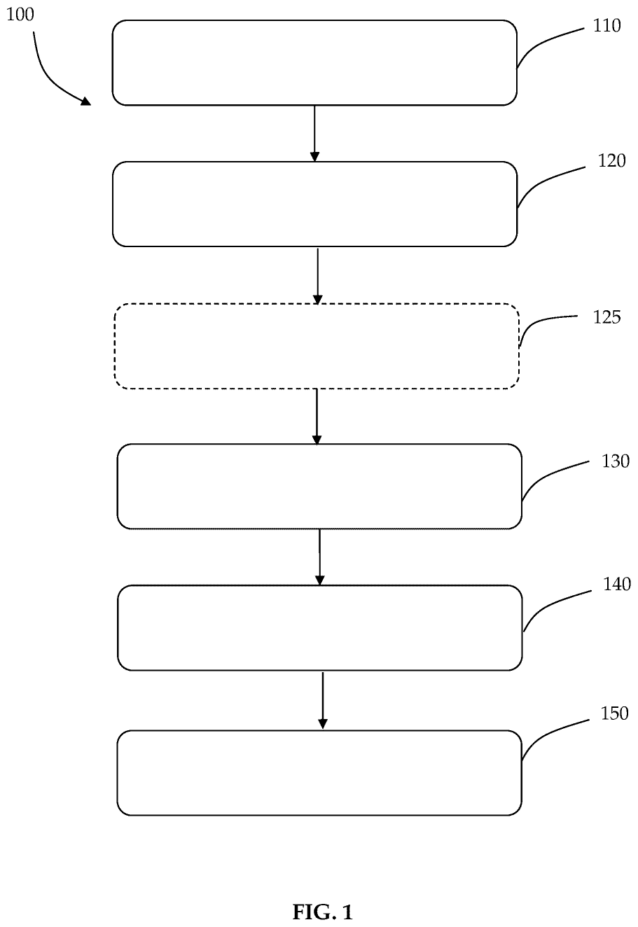

With reference to FIG. 1, a preferred embodiment of a process for making a layered material comprising a micro- and/or nanostructured layer in a resin, overall indicated with 100, is illustrated.

The process comprises a first step 110 in which a substrate 11 in solid material such as for example metal, ceramic, glass, stones or in polymeric material is made available. Alternatively, the substrate 11 is made of paper, for example in sheets or panels.

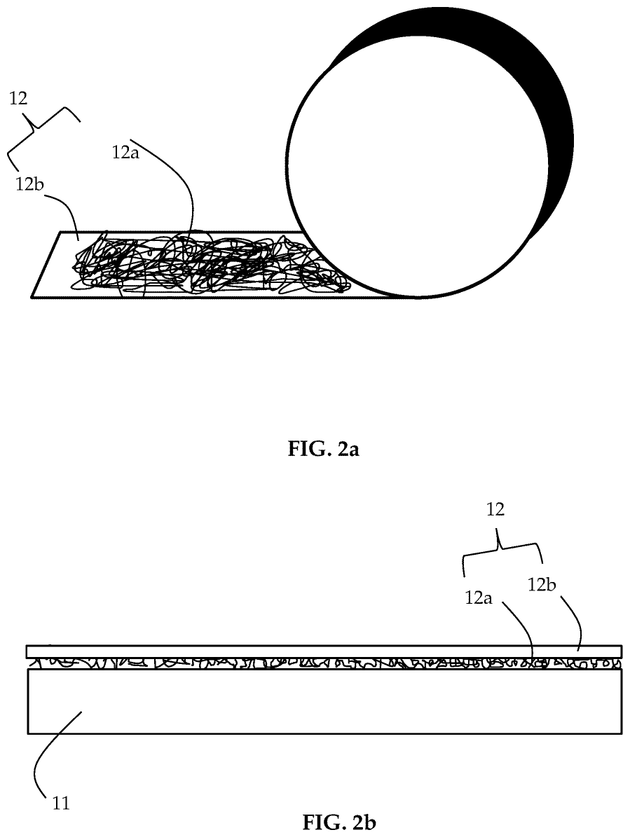

Thereafter (step 120), an adhesive sheet 12 comprising a layer of nanofibre nonwoven fabric 12a of a solidified thermosetting acrylic resin and/or of a solidified thermoplastic resin and optionally a peelable support layer 12b is made available. By way of example, the adhesive sheet 12 is made available in the form of a spool, as schematically illustrated in FIG. 2a.

The layer of nanofibre nonwoven fabric 12a is for example obtained by electrospinning. Such a layer 12a is presented as an off-white nanofibre web having a thickness comprised between 3-5 g/m² and preferably porosity greater than 50%, preferably greater than 60%, more preferably greater than 70%. The nanofibres forming the layer of nonwoven fabric 12a have a diameter preferably comprised between 200-1,500 nm, such as for example comprised between 200-400 nm.

In particular, the resin forming the layer of nanofibre nonwoven fabric 12a is configured to generate a micro- and/or nanostructure of accumulations of resin when subjected to a heat treatment cycle at a heating temperature sufficient to cause a collapse of the layer of nonwoven fabric, such as to render it completely transparent to view. Once subjected to heat treatment, the layer of nanofibre nonwoven fabric 12a is therefore no longer visible, becoming transparent to view. At the same time, the temperature of the heat treatment cycle is selected in such a way as to prevent a degradation of the layer of nanofibre nonwoven fabric of thermosetting acrylic resin and/or thermoplastic resin.

In a preferred embodiment, the layer of nonwoven fabric 12a used to generate the micro- and/or nanostructure of accumulations of thermosetting acrylic resin is made in polycyanoacrylate and the heating temperature reached in the heat treatment cycle is chosen in the interval comprised between 150° C. and 190° C., preferably comprised between 160° C. and 180° C., even more preferably equal to about 170° C.

In a particularly preferred embodiment, the layer of nonwoven fabric 12a used to generate the micro- and/or nanostructure of accumulations of thermosetting acrylic resin is made in polycyanoacrylate having a molecular weight of at least 15,000 Da (2.49081·10⁻²³ kg). In this case the heating temperature reached in the heat treatment cycle is selected in the interval comprised between 190° C. and 260° C., preferably in the interval comprised between 200° C. and 250° C., even more preferably in the in the interval comprised between 210° C. and 240° C.

Thanks to the use of a resin having a softening temperature in the intervals indicated above, it is possible to extend the application range of the layered material obtained with the process according to the present invention. In fact, the micro- and/or nanostructured layer that is generated with the process according to the invention remains stable up to temperatures of about 200° C. and above.

In an alternative embodiment, the layer of nonwoven fabric 12a used to generate the micro- and/or nanostructure of accumulations of thermoplastic resin is made in polyvinylidene fluoride and the heating temperature reached in the heat treatment cycle is selected in the interval comprised between 130° C. and 170° C., preferably comprised between 140° C. and 160° C., even more preferably equal to about 150° C.

The peelable layer 12b is preferably made of silicone-impregnated cellulose, thus having the advantage of remaining adherent to the layer of nonwoven fabric 12a by electrostatic force.

In a subsequent step of the process (step 130), the substrate 11 is coated with the adhesive sheet 12 made available in the previous step as schematically illustrated in FIG. 2b.

A heating step 140 thus takes place which provides for heating the assembly comprising the substrate 11 coated by the adhesive sheet 12 for a time sufficient to bring the layer of nonwoven fabric 12a to the heating temperature, so that a phase transition of the layer of nonwoven fabric 12a of the adhesive sheet 12 takes place and thus a micro- and/or nanostructure of localized accumulations of resin is created.

In case the substrate 11 has low thermal conductivity it is possible to employ it in the process according to the present invention even if the phase transition of the layer of nonwoven fabric 12a requires that heating temperatures even much higher than the softening temperature and/or degradation temperature of the substrate itself be applied. In this case, however, the heating step must have a very short duration, less than one minute, such as for example comprised between 1 second and 1 minute or, preferably, between 1 second and 30 seconds.

Otherwise, in case of substrates having softening and/or degradation temperature higher than the heating temperature, the heating step 140 provides for heating the substrate 11 coated by the adhesive sheet 12 for a period of time equal to at least 5 minutes, preferably equal to at least 10 minutes, more preferably equal to at least 15 minutes.

According to a particularly advantageous embodiment, the heating step 140 provides for applying eddy electric currents to the substrate 11, thereby heating the assembly comprising the substrate 11 coated by the adhesive sheet 12 by induction. This allows the heating step 140 to be substantially shortened limiting the thickness of the heated substrate to the surface only.

According to this variant, the heating step 140 has a duration comprised between 1 second and 1 minute or, preferably, between 1 second and 30 seconds.

Alternatively, the heating step 140 provides for applying heat directly to the adhesive sheet 12 by conduction, convection or through infrared heating.

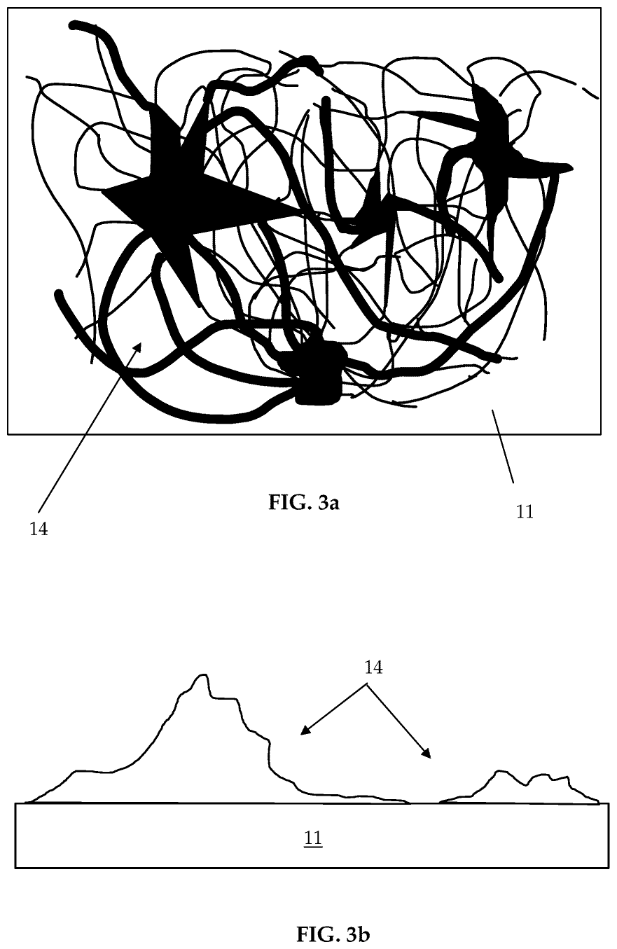

The heating step 140 causes the collapse of the layer of nonwoven fabric and its transition to a layer completely transparent to view. This creates a micro- and/or nanostructure 14 of localized accumulations of thermosetting acrylic resin and/or thermoplastic resin whose plan covers on average a surface of less than 20 μm² (square microns), preferably less than 15 μm², more preferably less than 10 μm², shown in schematic terms in FIGS. 3a and 3b. In particular, the micro- and/or nanostructure of transparent local accumulations of resin covers a surface of the substrate 11 comprised between 25%-60% of the surface of the substrate on which the adhesive sheet 12 has been applied, preferably comprised between 30%-50% of the surface of the substrate on which the adhesive sheet 12 has been applied, more preferably equal to about 40% of the surface of the substrate on which the adhesive sheet 12 has been applied.

Depending on the specific application, a step 150 of removing the peelable support layer 12b also takes place before or after the heating step 140.

A layered material comprising a substrate and a micro- and/or nanostructured adhesive layer in thermosetting acrylic resin and/or thermoplastic resin and completely transparent to view is thus obtained. In the case of thermosetting acrylic resin, the layered material thus obtained is characterized by particular hydrophobic properties and/or low coefficient of friction and/or in any case excellent adhesion to a second substrate in case the layered material comprises a second substrate which, with the first, closes the micro- and/or nanostructured layer like a sandwich.

The layered material is particularly suitable for a plurality of different applications depending on the particular material composing the substrate.

By way of example, the Applicant has identified the possibility of using the layered material thus obtained starting from a metallic substrate as the outer coating material of aircraft in order to obtain an outer coating that does not allow the accumulation of ice, for example on the wings of the aircraft. In this case, a micro- and/or nanostructured layer in thermosetting acrylic resin is applied which, by its nature, has nano-roughnesses that trap air bubbles between the surface of the substrate and which, preferably, incorporates a layer of nanofibres in a material with low roll-off angle when applied as a coating of a surface, so as to facilitate the detachment of any ice that forms on the same.

Within the scope of the present description and in the appended claims by “a material with low roll-off angle when applied as a coating of a surface” it is intended to mean a material having roll-off angle less than 65°, preferably less than 20°, more preferably less than 5°, such as for example polytetrafluoroethylene (PTFE).

By way of further example, the Applicant has identified the possibility of using the layered material thus obtained starting from a paper substrate, as a sealing material for jars, for example glass or plastic jars. In this case, a micro- and/or nanostructured layer in thermoplastic resin is applied to the paper substrate, which forms a coating layer that makes the paper substrate watertight and allows it to be welded to the jar, for example by ultrasonic techniques.

In particular, the step of making available 120 the adhesive sheet 12 provides for supplementing (step 125) the layer of nanofibre nonwoven fabric 12a of thermosetting acrylic resin and/or thermoplastic resin of the adhesive sheet with nano-elements in a material that is different with respect to said resin, such as for example nanoparticles 13 and/or nanotubes and/or second nanofibres 13′ in a different material.

For example, the layer of nanofibre nonwoven fabric 12a is immersed in a solution comprising a dispersion of nanoparticles 13 in an active material, such as semiconductor nanoparticles, such as for example the quantum dots, conductive nanoparticles, nanoparticles in bioactive material, or magnetic nanoparticles.

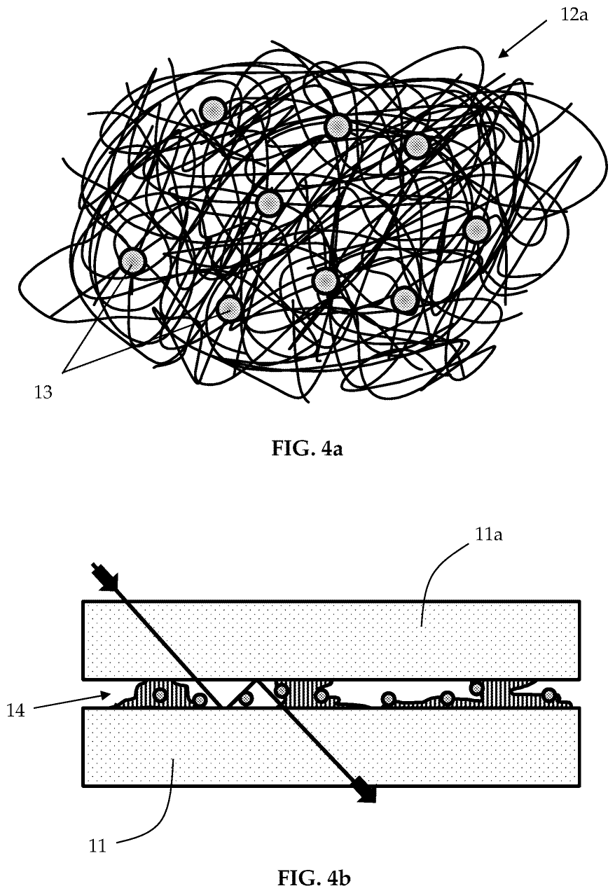

Then the layer of nanofibre nonwoven fabric 12a, impregnated with nanoparticles 13 in active material (shown in schematic terms in FIG. 4a) is allowed to dry and subsequently applied to the peelable support layer 12b and then used to coat the substrate 11.

In a preferred embodiment of the process for making a layered material, the peelable support layer 12b is removed (step 150) from the layer of nanofibre nonwoven fabric 12a prior to the heating step 140 and, the layer of nanofibre nonwoven fabric 12a is coated with a second substrate 11a, for example glass, so that the layer of nanofibre nonwoven fabric 12a is interposed between the two substrates 11,11a. Subsequently, the heating step 140 takes place which in this case cause the two substrates 11,11a to glue to each other. In fact, between the two substrates a transparent micro- and/or nanostructure 14 of accumulations of thermosetting acrylic resin and/or thermoplastic resin is created which achieve a gluing for micro- and/or nanodots between the two substrates 11,11a shown in FIG. 4b. Between the two substrates 11,11a, the nanoparticles 13 in active material remain also enclosed and trapped, which are thus distributed in an extremely homogeneous way along the interface surface between the two substrates 11,11a.

In case the nanoparticles in active material are for example quantum dots, the resulting layered material can be used to make photovoltaic panels, advantageously obtaining a structure in which the quantum dots are protected from the weather. It is also possible to supplement the layer of nanofibre nonwoven fabric 12a with a plurality of quantum dots of different types to achieve a progressive energy recovery. Still, it is possible to supplement the layer of nanofibre nonwoven fabric 12a with quantum dots so as to obtain a variable density of such particles in the thickness of the adhesive micro- and/or nanostructure. Alternatively or additionally, it is possible to provide a plurality of substrates bound to each other in pairs by means of transparent micro- and/or nanostructures of accumulations of thermosetting acrylic resin and/or thermoplastic resin obtained through the process according to the present invention and which incorporate densities different from each other of quantum dots.

In case the nanoparticles in active material are conductive nanoparticles, such as for example graphene or metallic nanoparticles, by means of the process according to the present invention it is possible to make a surface or a conductive track bound to a substrate 11, such as for example a wall. To this end the substrate 11 is coated with the adhesive sheet 12 supplemented with conductive nanoparticles 13 and is then subjected to the heating step 140 which causes the transformation of the layer of nanofibre nonwoven fabric 12a of the adhesive sheet 12 in the transparent micro- and/or nanostructure of accumulations of thermosetting acrylic resin and/or thermoplastic resin. In this case, such a transparent micro- and/or nanostructure of accumulations of thermosetting acrylic resin and/or thermoplastic resin incorporates a uniform distribution of conductive nanoparticles that make such a structure itself conductive. In order to make particular tracks or conductive circuits, a step of ablation, for example by laser, of the nanofibres that surround the track or the circuit to be made takes place.

Alternatively, if the layer of nanofibre nonwoven fabric 12a supplemented with conductive nanoparticles is coated with a second substrate 11a, a transparent conductive film, also known by the acronym TCF (Transparent Conducting Film) can be made.

In case the nanoparticles in active material are bioactive nanoparticles, such as for example titanium dioxide, copper or alloys thereof, by means of the process according to the present invention it is possible to make a self-sanitizing and completely transparent surface bound to a substrate 11, such as for example a metallic surface in order to make handrails or handles. To this end, the substrate 11 is coated with the adhesive sheet 12 supplemented with bioactive nanoparticles and is then subjected to the heating step 140 which causes the transformation of the layer of nanofibre nonwoven fabric 12a of the adhesive sheet 12 in the transparent micro- and/or nanostructure of accumulations of thermosetting acrylic resin and/or thermoplastic resin. In this case, such a transparent micro- and/or nanostructure of accumulations of thermosetting acrylic resin and/or thermoplastic resin incorporates a uniform distribution of bioactive nanoparticles 13 and is completely hidden from view, not altering the original appearance of the substrate 11.

In case the nanoparticles in active material are magnetic nanoparticles, such as for example nanoparticles in an ferrous mineral such as for examples magnetite, by means of the process according to the present invention it is possible to make a magnetized sheet for the implementation of actuators. To this end the substrate 11 is preferably a flexible film and is coated with the adhesive sheet 12 supplemented with magnetic nanoparticles 13 and is then subjected to the heating step 140 which causes the transformation of the layer of nanofibre nonwoven fabric 12a of the adhesive sheet 12 in the transparent micro- and/or nanostructure of accumulations of thermosetting acrylic resin and/or thermoplastic resin. In this case, such micro- and/or nanostructure of accumulations of thermosetting acrylic resin and/or thermoplastic resin incorporates a uniform distribution of magnetic nanoparticles. During the heat treatment a step of orienting the magnetic nanoparticles by applying an external magnetic field preferably takes place in order to obtain a magnetized sheet.

Alternatively or in addition to supplementing nanoparticles and/or nanotubes in active material, according to a variant of the invention, the layer of nanofibre nonwoven fabric 12a is made by electrospinning two distinct materials of which a first material is a thermosetting acrylic resin and/or thermoplastic resin, preferably polycyanoacrylate and/or polyvinylidene fluoride, and a second material is a different material from the first material.

By way of example, the second material is a material characterized by a low roll-off angle when applied as a coating of a surface, such as a material having a roll-off angle of less than 65°, preferably less than 20°, more preferably less than 5°, such as for example polytetrafluoroethylene.

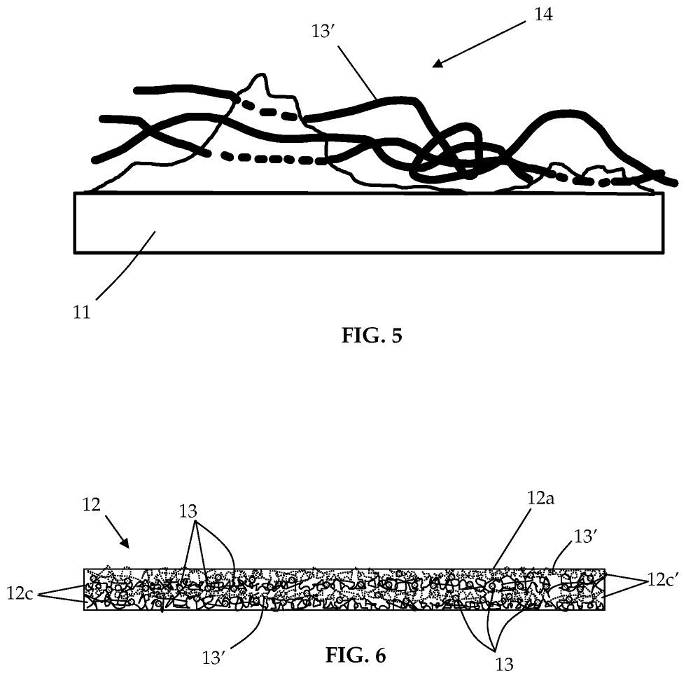

The layer of nanofibre nonwoven fabric 12a thus made comprises nanofibres of thermosetting acrylic resin and/or thermoplastic resin and second nanofibres 13′ of the material with low roll-off angle intertwined with each other. In this way, following the heating step 140, the nanofibres of thermosetting acrylic resin and/or thermoplastic resin form a transparent micro- and/or nanostructure 14 of accumulations of thermosetting acrylic resin and/or thermoplastic resin that incorporates the second nanofibres 13′ of the material with low roll-off angle, the latter being bound to the surface of the substrate 11, as shown in FIG. 5.

In particular, the step of supplementing 125 the layer of nanofibre nonwoven fabric 12a of thermosetting acrylic resin and/or thermoplastic resin of the adhesive sheet 12 with second nanofibres 13′ in a material with low roll-off angle provides for making the layer of nonwoven fabric 12a with a concentration gradient in the thickness of the layer such that there are a first face of the layer 12a in which the nanofibres of thermosetting acrylic resin and/or thermoplastic resin are predominantly exposed and a second face of the layer 12a in which the nanofibres in the material with low roll-off angle are predominantly exposed.

In this case, by coating the substrate 11 in such a way that the first face of the layer of nonwoven fabric 12a in which the nanofibres of thermosetting acrylic resin and/or thermoplastic resin are predominantly exposed is brought into contact with the surface of the substrate 11, following the heating step 140 the layer of nonwoven fabric 12a collapses adhering to the substrate 11 and incorporating the nanofibres 13′ of the material with low roll-off angle, which therefore remain bound to the substrate and exposed outwards, creating a coating of the substrate 11 at low roll-off angle.

As a further example, the second material with which electrospinning of the layer of nonwoven fabric 12a takes place is an elastomer, such as in particular polyurethane. The layer of nanofibre nonwoven fabric 12a thus made comprises nanofibres of thermosetting acrylic resin and/or thermoplastic resin and second elastomer nanofibres 13′ intertwined with each other.

In particular, the step of supplementing 125 the layer of nanofibre nonwoven fabric 12a of thermosetting acrylic resin and/or thermoplastic resin of the adhesive sheet 12 with second elastomer nanofibres 13′ provides for making the layer of nonwoven fabric 12a with a concentration gradient of the resin and of the second material along the thickness of the layer such as to define a plurality of sub-layers 12c, 12c′ each having an alternately prevalent concentration of resin (sub-layers 12c in FIG. 6) or of elastomer (sub-layers 12c′ in FIG. 6). In this way it is possible to obtain a layer of nonwoven fabric 12a which can be handled without deteriorating, even in the absence of a support layer 12b as the sub-layers having prevalent elastomer concentration can form a protective barrier in which the sub-layer having prevalent resin concentration is sandwiched and at the same time increase the mechanical properties of the layer of nonwoven fabric 12a. In this case, therefore, the layer of nonwoven fabric 12a comprising a plurality of sub-layers 12c constitutes the adhesive sheet 12, not requiring the use of a peelable support layer 12b.

According to preferred embodiments, the layer of nonwoven fabric 12a comprising a plurality of sub-layers 12c may be further supplemented with further nano-elements in a material that is different both with respect to the resin, and with respect to the second elastomer nanofibres, such as for example nano-particles 13 and/or nanotubes and/or further nanofibres, such as nanofibres in polytetrafluoroethylene.

1. A process for making a layered material comprising a micro- and/or nanostructured layer in a resin comprising the steps of:
providing a substrate configured to constitute a first layer of the layered material;
providing an adhesive sheet comprising at least one layer of nanofibre nonwoven fabric of a solidified thermosetting acrylic resin and/or of a solidified thermoplastic resin;
at least partially coating the substrate with the adhesive sheet; and
heating the assembly comprising the substrate coated by the adhesive sheet for a time interval sufficient to bring the layer of nanofibre nonwoven fabric to a heating temperature sufficient to cause a phase transition of the layer of nanofibre nonwoven fabric such as to generate a micro- and/or nanostructure of localized accumulations of thermosetting acrylic resin and/or thermoplastic resin;
wherein the step of providing the adhesive sheet comprises supplementing the layer of nanofibre nonwoven fabric of thermosetting acrylic resin and/or thermoplastic resin of the adhesive sheet with at least a plurality of nano-elements in a material different from the thermosetting acrylic resin and/or thermoplastic resin of the adhesive sheet.

2. The process according to claim 1,
wherein the solidified thermosetting acrylic resin is polycyanoacrylate (PECA); and/or
wherein the solidified thermoplastic resin is polyvinylidene fluoride (PVDF).

3. The process according to claim 1, wherein the at least one plurality of nano-elements comprises at least one of:
a plurality of nanoparticles,
a plurality of nanotubes and
a plurality of second nanofibres.

4. The process according to claim 3, wherein the plurality of second nanofibres comprises
a first plurality of second nanofibres made of a material characterized by having a roll-off angle of less than 65° when applied as a coating of a surface; and/or
a second plurality of second nanofibres made in an elastomer.

5. The process according to claim 1, wherein the adhesive sheet comprises a layer of nanofibre nonwoven fabric of a solidified thermosetting acrylic resin, and
wherein the heating temperature is between 150° C. and 260° C.

6. The process according to claim 1, wherein the adhesive sheet comprises a layer of nanofibre nonwoven fabric of a solidified thermoplastic resin, and
wherein the heating temperature is between 130° C. and 170° C.

7. The process according to claim 1, wherein the time interval (t) in which the assembly comprising the substrate coated by the adhesive sheet is subjected to heating is equal to at least 1 second.

8. The process according to claim 1, wherein the step of heating the assembly comprising the substrate coated by the adhesive sheet comprises applying heat to the substrate by induction heating and/or by infrared heating.

9. The process according to claim 1, wherein the substrate is selected from the group consisting of metal, ceramic, glass, stone, polymeric material, and paper.

10. The process according to claim 1, wherein the step of supplementing comprises immersing the layer of nanofibre nonwoven fabric in a solution comprising a dispersion of nano-elements and/or spraying the layer of nanofibre nonwoven fabric with a solution comprising a dispersion of nano-elements.

11. The process according to claim 1, wherein the nano-elements are selected from the group consisting of:
conductive nano-elements;
semiconductor nano-elements;
nano-elements in bioactive material; and
magnetic nano-elements.

12. The process according to claim 11, comprising the additional step of applying a magnetic field to the layered material to orient the nano-elements, in case the nano-elements are magnetic nano-elements.

13. The process according to claim 1, wherein the layer of nanofibre nonwoven fabric has a thickness between 3-5 g/m2, and/or a porosity greater than 50%, and is formed by nanofibres having a diameter between 200-1,500 nm.

14. The process according to claim 1, wherein the step of providing the adhesive sheet comprises making the layer of nanofibre nonwoven fabric by electrospinning.

15. The process according to claim 14, wherein the step of supplementing comprises making the layer of nanofibre nonwoven fabric by electrospinning of nanofibres in at least two distinct materials, of which a first material of the at least two distinct materials is the thermosetting acrylic resin and at least a second material of the at least two distinct materials is a material different from the thermosetting acrylic resin, such as a material characterized by having a roll-off angle of less than 65°.

16. The process according to claim 15, wherein the step of making the layer of nanofibre nonwoven fabric by electrospinning of nanofibres in at least two distinct materials comprises making the layer of nonwoven fabric in a plurality of sub-layers, wherein in each sub-layer a material of the at least two distinct materials is present in a prevalent concentration such as greater than 50%.

17. The process according to claim 1, wherein the adhesive sheet additionally comprises a peelable support layer, the peelable support layer being removed from the layer of nanofibre nonwoven fabric or from the micro- and/or nanostructure of localized accumulations of acrylic resin before or after the heating step.

18. An adhesive sheet for use in a process for making a layered material comprising a micro- and/or nanostructured layer in a resin, the adhesive sheet comprising
a layer of nanofibre nonwoven fabric of a thermosetting acrylic resin and/or a solidified thermoplastic resin, wherein the layer of nanofibre nonwoven fabric is supplemented with at least a plurality of nano-elements in a material different from the thermosetting acrylic and/or thermoplastic resin, in a material different from the thermosetting acrylic resin and/or from the thermoplastic resin; and
a peelable support layer.

19. The adhesive sheet for use in a process for making a layered material comprising a micro- and/or nanostructured layer in a resin according to claim 18, comprising a layer of nanofibre nonwoven fabric of a thermosetting acrylic resin and/or a solidified thermoplastic resin, wherein the layer of nanofibre nonwoven fabric is supplemented with nano-elements made in the form of a first plurality of second nanofibres in a material different from the thermosetting acrylic resin and/or from the thermoplastic resin, and wherein the layer of nanofibre nonwoven fabric comprises a plurality of sub-layers, wherein in each of the sub-layers there is alternatively in a prevalent concentration (a) the thermosetting acrylic resin and/or the thermoplastic resin or (b) the material different from the thermosetting acrylic resin and/or from the thermoplastic resin.

20. The adhesive sheet according to claim 19, wherein the layer of nanofibre nonwoven fabric is supplemented with at least a plurality of nano-elements in a material different from the thermosetting acrylic resin and/or from the thermoplastic resin, in a material different from the thermosetting acrylic resin and/or from the thermoplastic resin.

21. The adhesive sheet according to claim 20, wherein the at least one second plurality of second nanofibres is made in a material characterized by having a roll-off angle of less than 65° when applied as a coating of a surface.
